(19) United States
(12) Patent Application Publication
(10) Pub. No.: US 2019/0187527 A1
(43) Pub. Date: Jun. 20, 2019

(54) ARRAY SUBSTRATE, ARRAY SUBSTRATE PREPARATION METHOD AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Zhixiong JIANG, Shenzhen (CN)

(21) Appl. No.: 16/000,019

(22) Filed: Jun. 5, 2018

Related U.S. Application Data
(63) Continuation of application No. PCT/CN2018/072718, filed on Jan. 15, 2018.

(30) Foreign Application Priority Data
Dec. 19, 2017 (CN) 201711379556.6

(51) Int. Cl. G02F 1/1362; H01L 27/12; G02F 1/1335; G02F 1/1368; G09G 3/36

(52) U.S. Cl. CPC G02F 1/136286; H01L 27/124; G09G 3/3607; G02F 1/133514; G02F 1/1368; H01L 27/1262

(57) ABSTRACT

The present disclosure provides an array substrate, an array substrate preparation method and a display device. The array substrate includes a substrate, a plurality of spaced scan lines and a plurality of spaced data lines arranged at the same side of the substrate. The data lines are cross insulated from the scan lines, a first pixel region, a second pixel region and a TFT region are formed between n^{th} row scan line, (n+2)^{th} row scan line, m^{th} column data line and (m+1)^{th} column data line, the TFT region is located between the first pixel region and the second pixel region, and the TFT region is configured to provide a TFT device, all the TFT regions on the array substrate are covered with a protective layer, the material of the protective layer corresponding to all the TFT regions is the same.

### RELATED APPLICATIONS

This application is a continuation application of PCT Patent Application No. PCT/CN2018/072718, filed Jan. 15, 2018, which claims the priority benefit of Chinese Patent Application No. CN 201711379556.6, filed Dec. 19, 2017, which is herein incorporated by reference in its entirety.

### FIELD OF THE DISCLOSURE

The present disclosure relates to a display technology field, and more particularly to an array substrate, an array substrate preparation method and a display device.

### BACKGROUND OF THE DISCLOSURE

The liquid crystal display device is widely used because of its small size, light weight and good display effect. The liquid crystal display device generally includes an array substrate, a color filter substrate, and a liquid crystal layer. The array substrate and the color filter substrate are relatively spaced apart to form a receiving space for receiving the liquid crystal layer. The array substrate generally includes a plurality of thin film transistors (TFTs) distributed in a matrix. However, TFTs are easily eroded by water and oxygen because of the poor sealing of the liquid crystal display device, which leads to the deterioration of the performance of the TFT device, thereby affecting the display effect of the liquid crystal display device.

### SUMMARY OF THE DISCLOSURE

The present disclosure provides an array substrate, including a substrate, a plurality of spaced scan lines and a plurality of spaced data lines arranged at the same side of the substrate, wherein the data lines are cross insulated from the scan lines, a first pixel region, a second pixel region and a TFT region are formed between n^{th} row scan line, (n+2)^{th} row scan line, m^{th} column data line and (m+1)^{th} column data line, the TFT region is located between the first pixel region and the second pixel region, and the TFT region is used to provide a TFT device, all the TFT regions on the array substrate are covered with a protective layer, the material of the protective layer corresponding to all the TFT regions is the same, wherein n is a positive integer greater than or equal to 1, and m is a positive integer greater than or equal to 1.

The array substrate of the present disclosure includes a plurality of spaced scan lines and a plurality of spaced data lines, the data lines are cross insulated from the scan lines, a first pixel region, a second pixel region and a TFT region are formed between n^{th} row scan line, (n+2)^{th} row scan line, m^{th} column data line and (m+1)^{th} column data line, the TFT region is located between the first pixel region and the second pixel region, and the TFT region is used to provide a TFT device, all the TFT regions on the array substrate are covered with a protective layer. The protective layer can play a role of blocking water and oxygen, forming a seal on the liquid crystal display device. Further, the material of the protective layer corresponding to all the TFT regions is the same. That is, the same material is used to simultaneously cover the surface of the TFT device to ensure that the protective layer of the same material has the same effect on the electrical characteristics of the TFT device, so as to improve the electrical consistency of the TFT device and improve the display quality of the LCD panel.

The present disclosure further provides an array substrate preparation method, including:

providing a substrate;
forming a TFT device, a plurality of spaced scan lines, and a plurality of spaced data lines cross-insulated with the scan lines on the same side of the substrate;
forming a protective layer covering the TFT device, and the material of the protective layer corresponding to all the TFT devices is the same.

The present disclosure also provides a display device. The display device includes the array substrate as described above.

### BRIEF DESCRIPTION OF THE DRAWINGS

To describe the structural features and effectiveness of the present disclosure more clearly, the following detailed description is accompanied with the accompanying drawings and specific embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a top view of the array substrate according to the embodiment of the present disclosure.

FIG. 2 is a schematic structural diagram of an AA cross-sectional view of the array substrate according to the embodiment of the present disclosure.

FIG. 3 is a schematic structural diagram of a first pixel region or a second pixel region covering a red color resist according to the first embodiment of the present disclosure.

FIG. 4 is a schematic structural diagram of a first pixel region or a second pixel region covering a green color resist according to the first embodiment of the present disclosure.

FIG. 5 is a schematic structural diagram of a first pixel region or a second pixel region covering a blue color resist according to the first embodiment of the present disclosure.

FIG. 6 to FIG. 9 are schematic structural diagrams of the first pixel region or the second pixel region covering protective layer provided by other embodiments of the present disclosure.

FIG. 10 is a schematic structural diagram of the second embodiment of the present disclosure including a plurality of sub-protective layers.

FIG. 11 is a flowchart of the array substrate preparation method according to the embodiment of the present disclosure.

FIG. 12 is a partial flow chart of array substrate preparation method according to the embodiment of the present disclosure.

FIG. 13 is a schematic structural diagram corresponding to step S310 of array substrate preparation method according to the embodiment of the present disclosure.

FIG. 14 is a schematic structural diagram corresponding to step S320 of array substrate preparation method according to the embodiment of the present disclosure.

FIG. 15 is a partial flow chart of array substrate preparation method according to the embodiment of the present disclosure.

FIG. 16 is a schematic structural diagram of the display device according to the embodiment of the present disclosure.

### DETAILED DESCRIPTION OF PREFERRED EMBODIMENTS

The technical solutions in the embodiments of the present disclosure are clearly and completely described below with reference to the accompanying drawings in the embodiments of the present disclosure. Obviously, the described embodiments are only a part but not all of the embodiments of the present disclosure. All other embodiments obtained by a person of ordinary skill in the art based on the embodiments of the present disclosure without creative efforts shall fall within the protection scope of the present disclosure.

Reference herein to “an embodiment” means that a particular feature, structure, or characteristic described in connection with the embodiment may be included in at least one embodiment of the disclosure. The appearances of the phrase in various places in the specification are not necessarily all referring to the same embodiment, nor are separate or alternative embodiments mutually exclusive of other embodiments. As one of ordinary skill in the art willingly and implicitly appreciate, the embodiments described herein may be combined with other embodiments.

In order to make the technical solutions provided by the embodiments of the present disclosure clearer, the foregoing solutions are described in detail below with reference to the accompanying drawings.

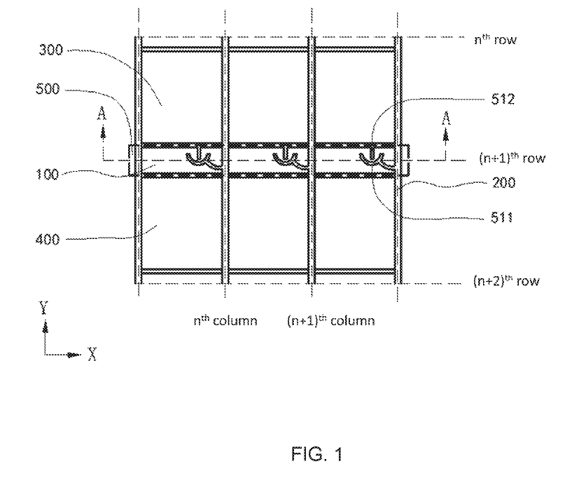

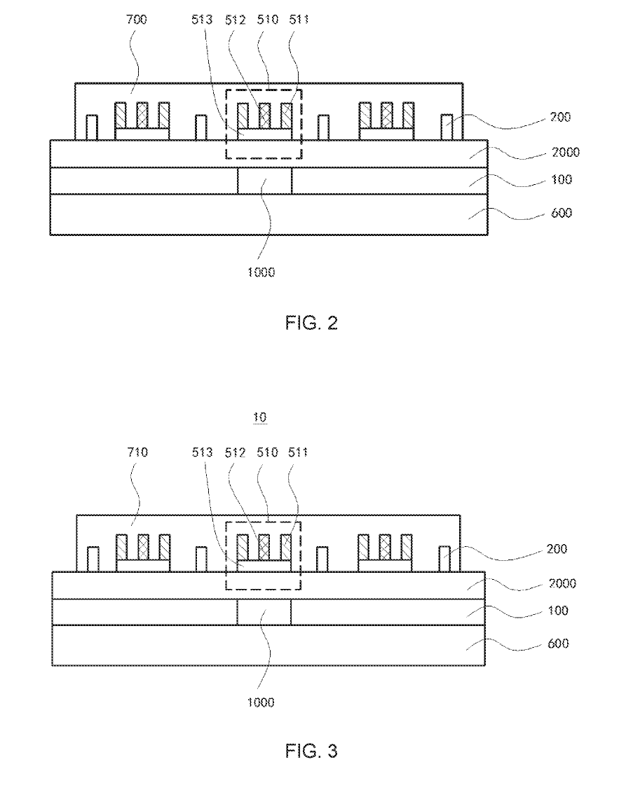

Referring to FIG. 1 and FIG. 2, FIG. 1 is a schematic structural diagram of a top view of the array substrate according to the embodiment of the present disclosure. FIG. 2 is a schematic structural diagram of an AA cross-sectional view of the array substrate according to the embodiment of the present disclosure. The array substrate 10 includes a substrate 600, a plurality of spaced scan lines 100 and a plurality of spaced data lines 200 disposed on the same side of the substrate 600. The data lines 200 are cross insulated from the scan lines 100. A first pixel region 300, a second pixel region 400 and a TFT region 500 are formed between n^{th} row scan line 100, (n+2)^{th} row scan line 100, m^{th} column data line 200 and (m+1)^{th} column data line 200, the TFT region 500 is located between the first pixel region 300 and the second pixel region 400, and the TFT region 500 is used to provide a TFT device 510, all the TFT regions 500 on the array substrate are covered with a protective layer 700, the material of the protective layer 700 corresponding to all the TFT regions 500 is the same, wherein n is a positive integer greater than or equal to 1, and m is a positive integer greater than or equal to 1.

For example, the scan lines 100 extend in a first direction and the scan lines 100 are spaced apart along the second direction, the data lines 200 extend in the second direction and the data lines 200 are spaced apart along the first direction, and the data lines 200 are insulated from the scan lines 100. The first direction may be the X direction or the Y direction, and the second direction may also be the X direction or the Y direction. When the first direction is the X direction, the second direction is the Y direction; and when the first direction is the Y direction, the second direction is the X direction. In the embodiment of the present disclosure, the first direction is the X direction and the second direction is the Y direction as an example.

The substrate 600 is a transparent substrate, such as a glass substrate or a plastic substrate, and may be a flexible substrate.

The first pixel region 300 and the second pixel region 400 are light emitting regions, the first pixel region 300 may be any one of a red subpixel (R), a green subpixel (G), a blue subpixel (B) and a white subpixel (W). Correspondingly, the first pixel region 300 covers the color resist of the corresponding color. For example, when the first pixel region 300 is a red subpixel, the first pixel region 300 covers a red color resist. The second pixel region 400 may be any one of a red subpixel (R), a green subpixel (G), a blue subpixel (B) and a white subpixel (W). Correspondingly, the second area 300 covers the color hue of the corresponding color. For example, when the second pixel region 400 is a green subpixel, the second region 400 covers a green color resist.

The TFT region 500 is configured to dispose a TFT device 510 including a gate 1000, a gate insulating layer 2000, an active layer 513, a drain 511 and a source 512. Wherein the gate 1000 and the scan line 100 are electrically connected, the gate insulating layer 2000 covers the gate 1000 and the scan line 100, the active layer 513 is disposed on the surface of the gate insulating layer 2000 away from the gate 1000 and the scan line 100, in the present embodiment, the active layer 513 adopts a silicon island structure. The drain 511 is electrically connected to the data line 200. The source 512 and the drain 511 are disposed on a surface of the active layer 513 away from the gate insulating layer 2000, and the source 512 and the drain 511 are spaced apart. In the present embodiment, the drain 511 is curved to form a receiving space, and the source 512 is disposed in the receiving space. Under the control of the gate 1000, a larger channel current can be formed between the source 512 and the drain 511, thereby improving the reaction speed of the TFT device.

The first pixel region 300 is located between n^{th} row scan line 100 and (n+1)^{th} row scan line 100, the second pixel region 400 is located between (n+1)^{th} row scan line 100 and (n+2)^{th} row scan line 100, (n+1)^{th} row scan line 100 passes through the TFT region 500.

Optionally, the protective layer 700 covered by all the TFT regions 500 on the array substrate 10 is the red color resist 710, and the protective layer 700 is integrated with the first pixel region 300 or the red color resist 710 covered by the second pixel region 400 (see FIG. 3).

In other words, when the red color resist 710 covering the first pixel region 300 or the second pixel region 400 is formed, the red color resist 710 covering all the TFT regions 500 on the array substrate 10 is also formed at the same time. That is, the red color resist 710 serves as the protective layer 700 of all the TFT regions 500. The red color resist 710 and the protective layer 700 are formed in the same process, which can save the process.

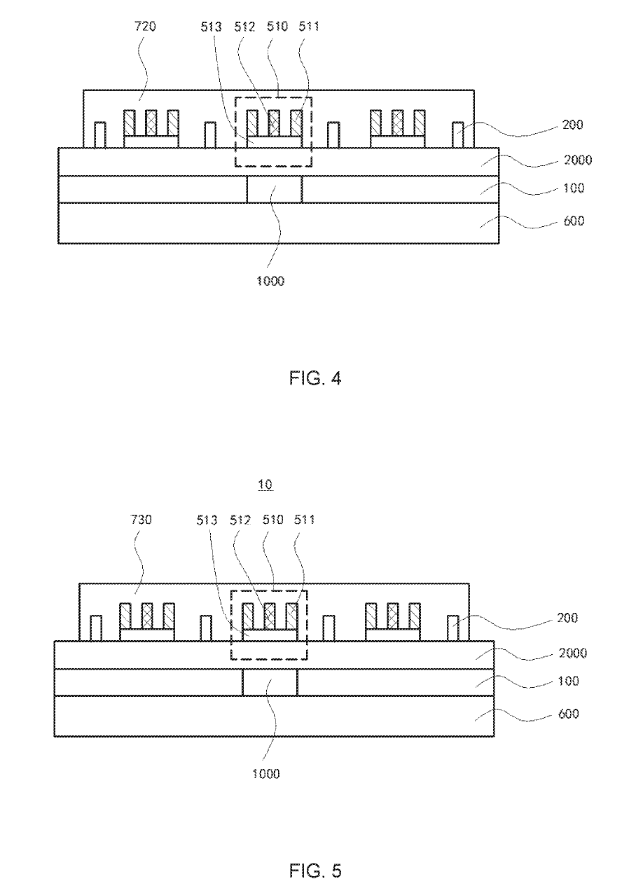

Alternatively, the protective layer 700 covered by all the TFT regions 500 on the array substrate 10 is a green color resist 720, the protective layer 700 is integrated with the first pixel region 300 or the green color filter 720 covered by the second pixel region 400 (see FIG. 4).

In other words, when the green color resist 720 covering the first pixel region 300 or the second pixel region 400 is formed, the green color filters 720 covering all the TFT regions 500 on the array substrate 10 are formed at the same time. That is, the green color resist 720 serves as the protective layer 700 of all the TFT regions 500. The green color resist 720 and the protective layer 700 are formed in the same process, which can save the process.

Alternatively, the protective layer 700 covered by all the TFT regions 500 on the array substrate 10 is a blue color resist 730, and the protective layer 700 is integrated with the first pixel region 300 or the blue color resist 730 covered by the second pixel region 400 (see FIG. 5).

In other words, when the blue color resist 730 covering the first pixel region 300 or the second pixel region 400 is formed, the blue color resist 730 covering all the TFT regions 500 on the array substrate 10 is formed at the same time. That is, the blue color resist 730 serves as the protective layer 700 of all the TFT regions 500. The blue color resist 730 and the protective layer 700 are formed in the same process, which can save the process.

In another embodiment, the protective layer 700 covered by all the TFT regions 500 on the array substrate 10 may be a white material, a black material, or a photoresist.

Optionally, the protective layer 700 covered by all the TFT regions 500 on the array substrate 10 may be a transparent photoresist. PFA is a kind of transparent photoresist, which is usually used to cover the RGB color resist instead of the PV2 protective layer, Preferably, in the present disclosure, the PFA is used to cover the TFT region to form a protective layer.

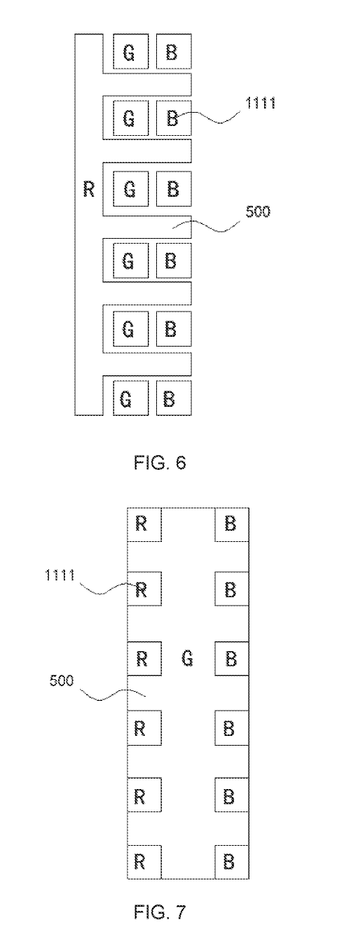

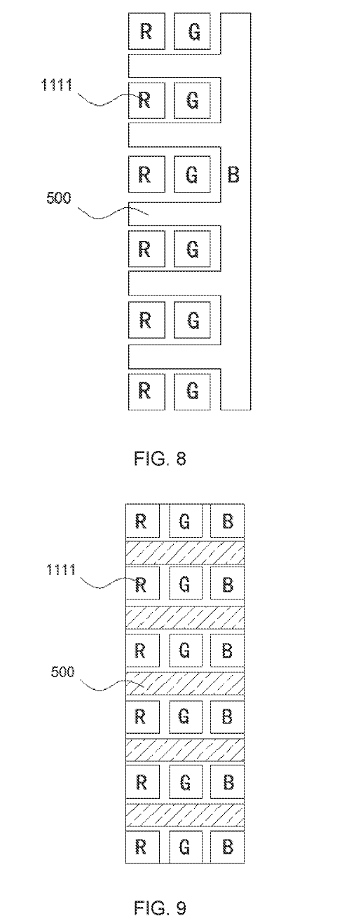

Referring to FIG. 6 to FIG. 9, in order to facilitate understanding of the intent of the present disclosure, FIG. 6 to FIG. 9 are, respectively, in other embodiments, the TFT area is indicated by reference numeral 500, the pixel area is denoted by reference numeral 1111. FIG. 6 is a schematic structural diagram of the TFT region 500 covering only one color resist layer and the color resist layer being a red color resist (R color resist), FIG. 7 is a schematic structural diagram of the TFT region 500 covering only one color resist layer and the color resist layer being a green color resist (G color resist), FIG. 8 is a schematic structural diagram of the TFT region 500 covering only one color resist layer and the color resist layer having a blue color resist (B color resist), FIG. 9 is a schematic structural diagram of the TFT region 500 covering only one color resist layer, and the color resist layer being a PFA material, a W material, a PS material, or a BM material.

The array substrate provided by the technical solution includes a plurality of spaced scan lines and a plurality of spaced data lines, the data lines are cross insulated from the scan lines, a first pixel region, a second pixel region and a TFT region are formed between n^{th} row scan line, (n+2)^{th} row scan line, m^{th} column data line and (m+1)^{th} column data line, the TFT region is located between the first pixel region and the second pixel region, and the TFT region is used to provide a TFT device, all the TFT regions on the array substrate are covered with a protective layer. The protective layer can play a role of blocking water and oxygen, forming a seal on the liquid crystal display device. Further, the material of the protective layer corresponding to all the TFT regions is the same. That is, the same material is used to simultaneously cover the surface of the TFT device to ensure that the protective layer of the same material has the same effect on the electrical characteristics of the TFT device, so as to improve the electrical consistency of the TFT device and improve the display quality of the LCD panel.

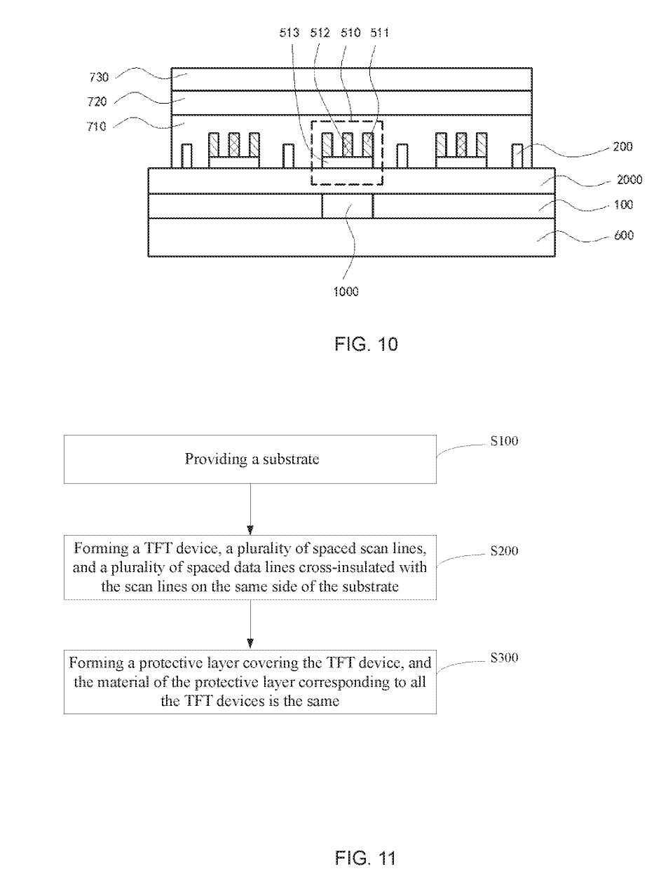

In another embodiment, the protective layer 700 includes a plurality of stacked sub-protective layers, and the plurality of sub-protective layers have different materials. Referring to FIG. 10. taking the protective layer 700 as an example including three sub-protective layers, the protective layer 700 includes a first sub-protective layer 710, a second sub-protective layer 720, and a third sub-protective layer 730. For example, the first sub-protective layer 710 is a red color resist, the second sub-protective layer 720 is a green color resist, the third sub-protective layer 730 is a blue color resist. For the entire TFT device, the same color resist material is covered, which is a red color resist, a green color resist and a blue color resist stacked in turn. Since TFT devices are covered by the same color resist material and have the same barrier ability to water and oxygen, they have the same effect on the electrical properties of the TFT devices, and the problem of electrical consistency of the TFT devices can be improved.

The TFT region of the array substrate provided by the technical solution is covered with a protective layer, and the protective layer includes a plurality of sub-protective layers arranged in layers, and the materials of the plurality of sub-protective layers are different. For the entire TFT device, the same color resist material is covered, and the material of the protective layer corresponding to all the TFT regions is the same, that is, the same material is used to cover the surface of the TFT device at the same time, since TFT devices are covered by the same color resist material, they have the same barrier ability against water and oxygen, so as to ensure that the protective layer of the same material has the same effect on the electrical characteristics of the TFT device. Thereby improving the electrical consistency of the TFT device and improving the display quality of the liquid crystal display panel.

Referring to FIG. 11, an embodiment of the present disclosure further provides an array substrate preparation method. The method for preparing the array substrate 10 includes, but is not limited to, steps S100, S200 and S300. The detailed description of the above steps S100, S200 and S300 is as follows.

S100. Providing a substrate 600.

The substrate 600 is a transparent substrate, such as a glass substrate or a plastic substrate, and may be a flexible substrate.

S200. Forming a TFT device 510, a plurality of spaced scan lines 100, and a plurality of spaced data lines 200 cross-insulated with the scan lines 100 on the same side of the substrate 600.

The TFT region 500 is used for disposing a TFT device 510 including a gate 1000, a gate insulating layer 2000, an active layer 513, a drain 511 and a source 512. Wherein the gate 1000 and the scan line 100 are electrically connected, the gate insulating layer 2000 covers the gate 1000 and the scan line 100, the active layer 513 is disposed on the surface of the gate insulating layer 2000 away from the gate 1000 and the scan line 100, in the present embodiment, the active layer 513 adopts a silicon island structure. The drain 511 is electrically connected to the data line 200. The source 512 and the drain 511 are disposed on the surface of the active layer 513 away from the gate insulating layer 2000, and the source 512 and the drain 511 are spaced apart. In the present embodiment, the drain 511 is curved to form a receiving space, and the source 512 is disposed in the receiving space. Under the control of the gate 1000, a larger channel current can be formed between the source 512 and the drain 511, thereby improving the reaction speed of the TFT device.

S300. Forming a protective layer 700 covering the TFT device 510, and the material of the protective layer 700 corresponding to all the TFT devices 510 is the same.

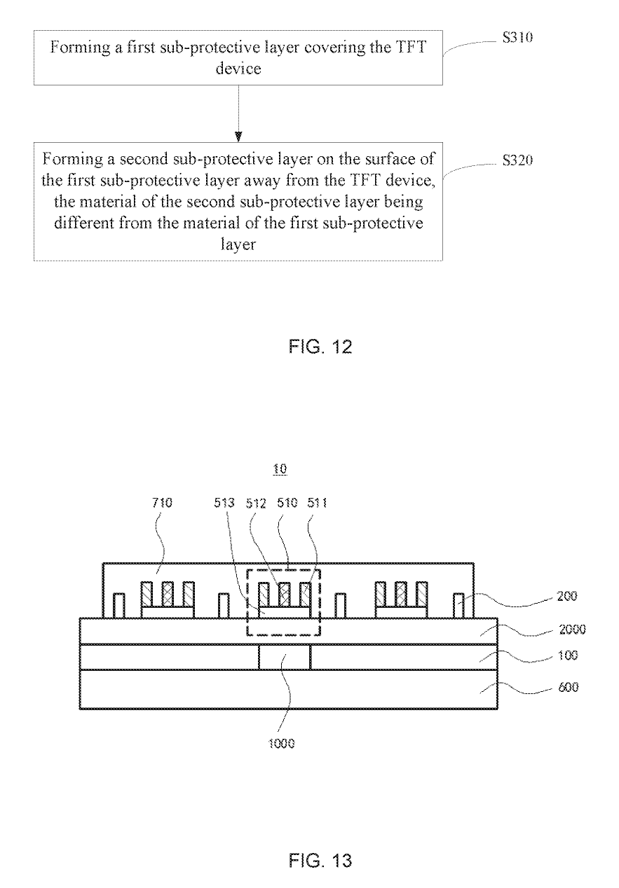

Referring to FIG. 12, the step of “S300. forming a protective layer covering the TFT device, and the material of the protective layer corresponding to all the TFT devices is the same” includes but not limited to steps S310 and S320. The details are described below with respect to steps S310 and S320.

S310. Forming a first sub-protective layer 710 covering the TFT device 510. See FIG. 13.

Optionally, the first sub-protective layer 710 covered by all the TFT devices 510 on the array substrate 10 may be a red color resist, a green color resist, or a blue color resist. The protective layer 700 covered by all the TFT devices 510 on the array substrate 10 may also be a transparent material, a white material, a black material, or a photoresist.

Optionally, the first sub-protective layer 710 covered by all the TFT devices 510 on the array substrate 10 may be a PFA material. PFA is a kind of transparent photoresist, which is usually used to cover the RGB color resist instead of the PV2 protective layer. Preferably, in the present disclosure, the PFA is used to cover the TFT region to form a protective layer.

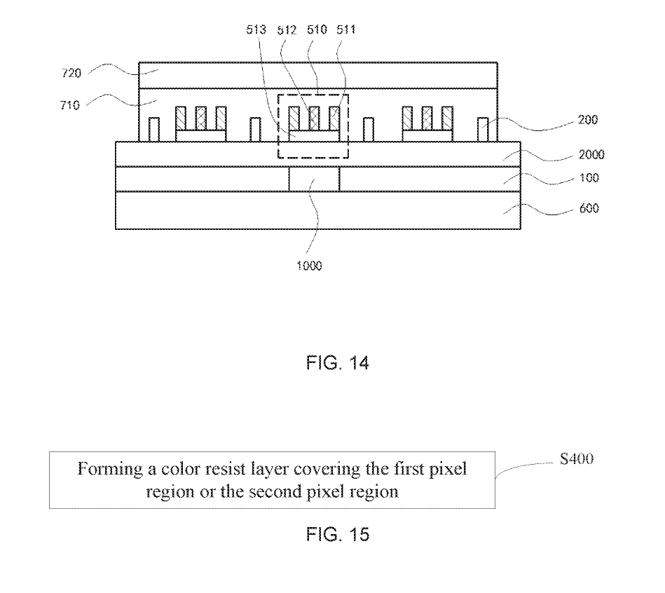

S320. Forming a second sub-protective layer 720 on the surface of the first sub-protective layer 710 away from the TFT device 510, the material of the second sub-protective layer 720 being different from the material of the first sub-protective layer 710. See FIG. 14.

Optionally, a second sub-protective layer 720 is formed on the surface of the first sub-protective layer 710 away from the TFT device 510, the second sub-protective layer 720 may be a red color resist, a green color resist, or a blue resist. The protective layer 700 covered by all the TFT devices 510 on the array substrate 10 may also be a PFA material, a white material, a black material, or a photoresist. The material of the second sub-protective layer 720 is different from the material of the first sub-protective layer 710.

In another embodiment, the array substrate 10 includes a substrate 600, a plurality of spaced scan lines 100 and a plurality of spaced data lines 200 disposed on the same side of the substrate 600. The data lines 200 are cross insulated from the scan lines 100. A first pixel region 300, a second pixel region 400 and a TFT region 500 are formed between n^{th} row scan line 100, (n+2)^{th} row scan line 100, m^{th} column data line 200 and (m+1)^{th} column data line 200, the TFT region 500 is located between the first pixel region 300 and the second pixel region 400, and the TFT region 500 is used to provide a TFT device 510, all the TFT regions 500 on the array substrate are covered with a protective layer 700, the material of the protective layer 700 corresponding to all the TFT regions 500 is the same, wherein n is a positive integer greater than or equal to 1, and m is a positive integer greater than or equal to 1. Referring to FIG. 15, the preparing method of the array substrate 10 further includes, but not limited to, step S400, and details about step S400 are as follows.

S400. Forming a color resist layer covering the first pixel region 300 or the second pixel region 400.

Optionally, the material of the protective layer 700 is the same as the material of the color resist layer, and the protective layer 700 and the color resist layer are formed in the same process. When the protective layer 700 and the color resist layer are formed together in the same process, unnecessary steps can be saved, thereby reducing the cost.

Optionally, the color resist layer may be a red color resist, a green resist, and a blue resist. The color resist layer is used for isolating the adverse effects of water and oxygen on the TFT device to protect the TFT device.

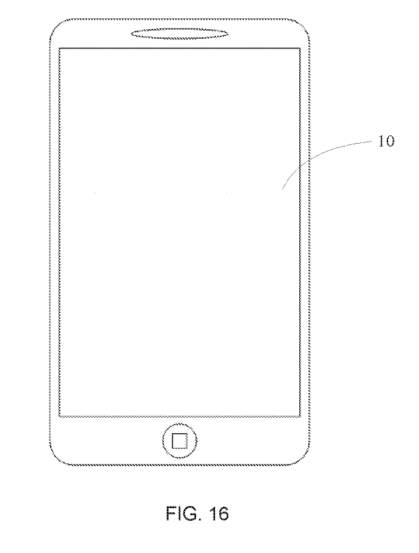

Referring to FIG. 16, FIG. 16 is a schematic structural diagram of a display device according to the embodiment of the present disclosure. The display device 1 includes an array substrate 10. The array substrate 10 may be the array substrate 10 provided in any one of the foregoing embodiments, and details are not described herein again. The display device 1 may be, but not limited to, an electronic book, a smart phone (such as an Android mobile phone, an iOS mobile phone, a Windows Phone mobile phone, etc.), a tablet PC, a palmtop computer, a laptop computer, a mobile Internet device (MID) or a wearable device.

The embodiments of the present disclosure are described in detail above. Specific examples are used herein to describe the principles and implementation manners of the present disclosure. The description of the foregoing embodiments is merely used to help understand the method and core idea of the present disclosure. Meanwhile, those skilled in the art may make modifications to the specific implementation manners and the application scope according to the idea of the present disclosure. To sum up, the contents of the description should not be construed as limiting the present disclosure.

What is claimed is:

1. An array substrate, comprising a substrate, a plurality of spaced scan lines and a plurality of spaced data lines arranged at the same side of the substrate, wherein the data lines are cross insulated from the scan lines, a first pixel region, a second pixel region and a TFT region are formed between n^{th} row scan line, (n+2)^{th} row scan line, m^{th} column data line and (m+1)^{th} column data line, the TFT region is located between the first pixel region and the second pixel region, and the TFT region is configured to provide a TFT device, all the TFT regions on the array substrate are covered with a protective layer, a material of the protective layer corresponding to all the TFT regions is the same, wherein n is a positive integer greater than or equal to 1, and m is a positive integer greater than or equal to 1.

2. The array substrate according to claim 1, wherein the protective layer comprises a plurality of stacked sub-protective layers and materials of the plurality of sub-protective layers are different.

3. The array substrate according to claim 1, wherein the first pixel region is located between n^{th} row scan line and (n+1)^{th} row scan line, the second pixel region is located between (n+1)^{th} row scan line and (n+2)^{th} row scan line, (n+1)^{th} row scan line passes through the TFT region.

4. The array substrate according to claim 1, wherein the protective layer covered all the TFT regions on the array substrate is a color resist layer.

5. The array substrate according to claim 4, wherein the color resist layer is a red color resist, the protective layer and the red color resist covered on the first pixel region or the second pixel region are an integral structure.

6. The array substrate according to claim 4, wherein the color resist layer is a green color resist, the protective layer and the green color resist covered on the first pixel region or the second pixel region covered are an integral structure.

7. The array substrate according to claim 4, wherein the color resist layer is a blue color resist, and the protective layer and the blue color resist covered on the first pixel region or the second pixel region covered are an integral structure.

8. The array substrate according to claim 1, wherein the protective layer covered all the TFT regions on the array substrate is a transparent photoresist.

9. An array substrate preparation method, comprising:
providing a substrate;
forming a TFT device, a plurality of spaced scan lines, and a plurality of spaced data lines cross-insulated with the scan lines on the same side of the substrate;
forming a protective layer covering the TFT device, and a material of the protective layer corresponding to all the TFT devices is the same.

10. A display device, comprising an array substrate comprising a substrate, a plurality of spaced scan lines and a plurality of spaced data lines arranged at the same side of the substrate, wherein the data lines are cross insulated from the scan lines, a first pixel region, a second pixel region and a TFT region are formed between n^{th} row scan line, (n+2)^{th} row scan line, m^{th} column data line and (m+1)^{th} column data line, the TFT region is located between the first pixel region and the second pixel region, and the TFT region is configured to provide a TFT device, all the TFT regions on the array substrate are covered with a protective layer, a material of the protective layer corresponding to all the TFT regions is the same, wherein n is a positive integer greater than or equal to 1, and m is a positive integer greater than or equal to 1.

11. The display device according to claim 10, wherein the protective layer comprises a plurality of stacked sub-protective layers and materials of the plurality of sub-protective layers are different.

12. The display device according to claim 10, wherein the first pixel region is located between n^{th} row scan line and (n+1)^{th} row scan line, the second pixel region is located between (n+1)^{th} row scan line and (n+2)^{th} row scan line, (n+1)^{th} row scan line passes through the TFT region.

13. The display device according to claim 10, wherein the protective layer covered all the TFT regions on the array substrate is a color resist layer.

14. The display device according to claim 13, wherein the color resist layer is a red color resist, and the protective layer and the red color resist covered on the first pixel region or the second pixel region are an integral structure.

15. The display device according to claim 13, wherein the color resist layer is a green color resist, and the protective layer and the green color resist covered on the first pixel region or the second pixel region are an integral structure.

16. The display device according to claim 13, wherein the color resist layer is a blue color resist, and the protective layer and the blue color resist covered on the first pixel region or the second pixel region covered is an integral structure.

17. The display device according to claim 10, wherein the protective layer covered all the TFT regions on the array substrate is a transparent photoresist.
